(19) United States
(12) Patent Application Publication
(10) Pub. No.: US 2010/0319900 A1
(43) Pub. Date: Dec. 23, 2010

(54) COMPOSITE MATERIAL HAVING HIGH THERMAL CONDUCTIVITY ND PROCESS OF FABRICATING SAME

(76) Inventor: Andrey Mikhailovich Abyzov, Saint Petersburg (RU)

Correspondence Address: Mrs. Maria Nilova;PATENTICA, BOX 1125, Saint Petersburg, 190000, omitted

(21) Appl. No.: 12/861,861

(22) Filed: Aug. 24, 2010

Related U.S. Application Data
(63) Continuation-in-part of application No. PCT/RU2009/000583, filed on Oct. 21, 2009.

(51) Int. Cl. F28F 7/00; B32B 5/16; B05D 7/00; C23C 14/34; B05D 1/12

(52) U.S. Cl. 165/185; 428/403; 427/212; 204/192.15; 427/180

(57) ABSTRACT

The invention relates to high thermal conductivity (TC) materials, in particular, to copper-diamond composite materials, which can be used as heat exchangers, heat sinks, heat spreaders for electronic and other devices and a method of production thereof. A high TC diamond-metal composite according to the invention has a TC above 500 W/(m*K) and comprises coated diamond particles in a metal or metal alloy matrix having a TC of not less than 300 W/(m*K), wherein the particles are coated with a single-layered continuous high surface area coating comprising a metal and/or carbide of a carbide-forming element selected from IV-VI Groups of the Periodic Table, the coating having a thickness of less than 500 nm and a certain surface texture to provide high TC of composite.

### CROSS-REFERENCES TO RELATED APPLICATIONS

This application claims the benefits from International Application PCT/RU2009/000583 filed on Oct. 21, 2009. The content of this application is hereby incorporated by reference and in its entirety.

### TECHNICAL FIELD

The invention relates to high thermal conductivity materials, in particular, to copper-diamond composite materials, which can be used as heat exchangers, heat sinks, heat spreaders for electronic devices (such as integrated circuits, lasers, X-ray tubes etc.), heat engines, in refrigerators (such as thermoelectric cooling systems, etc.) and a method of production thereof. A composite material according to the invention can be used in high-heat-load and high-heat-flux systems (for example, in synchrotron radiation sources and nuclear fusion reactors), and also in high speed thermal transfer devices (such as thermal sensor systems).

### BACKGROUND OF THE INVENTION

The present invention relates to composite materials useful in fabrication of heat sinks, heat exchangers and other devices, the efficiency of which is determined by the thermal conductivity (TC) of the material they are made of. The coefficient of TC is defined as heat flux, W/m² (energy per unit area per unit time) divided by temperature gradient, K/m (temperature difference per unit length). Amongst all known substances, certain forms of carbon possess maximal TC at temperatures close to room temperature. In the present application, unless otherwise stated, the TC is assumed in the temperature range of (20±100)° C. For pyrographite, the coefficient of TC in the x-y plane is as much as 2400 W/(m*K), whereas in a direction normal to the graphite layers, the coefficient is two orders of magnitude less. For example, heat sinks produced commercially by k-Core® [www.k-technology.com] consist of graphite plates with an in-plane TC (x-y) of 1700 W/(m*K) and a perpendicular TC (z) of around 10 W/(m*K), enclosed within a shell of encapsulating material. The disadvantage of such devices is the relatively low TC through the thickness of the plate, which necessitates the introduction of vias made of high-conductivity non-carbon material, in the z axis, complicating the construction of the device. In addition, the presence of the encapsulating shell significantly reduces the effective in-plane TC of the device as a whole, compared to the TC of the graphite core. Carbon fibers have a similarly high anisotropy of TC. For example, the carbon fiber Thornel® [www.cytec.com] derived from pitch, has an axial TC (along the fiber) of up to 1000 W/(m*K), with far lower radial TC.

Diamond is the only material, which possesses an extremely high isotropic TC; its TC may reach 2500 W/(m*K) in pure, single crystals without defects. Natural diamond powders, grains as the technical raw material have the limited distribution. Artificial diamond is produced on an industrial scale for tooling, and as abrasive (as diamond is the hardest known material). Synthetic diamond is commercially available in the following basic forms:

powder or grains, the particles or crystals size ranging from 5 nm to roughly 1 mm, which are produced at high pressures and temperatures, under conditions of diamond thermodynamic stability.

polycrystalline composites, produced by sintering particles of diamond at high pressure;

films, coatings and layers, produced by chemical vapor deposition (CVD) under non-equilibrium conditions.

Methods of obtaining layers of polycrystalline diamond for heat sinks using CVD are known in the art. For example, [Nakamura et al, U.S. Pat. No. 5,299,214] describes the production of layers of polycrystalline diamond with a thickness in the range of 10 μm to 1 mm, an area of around 10×10 mm, and a TC of 500-2000 W/(m*K) by means of plasma-enhanced chemical vapor deposition within radio-frequency or microwave discharges or near a tungsten hot filament (1900-2200° C.) from a gaseous mixture of hydrocarbons (CH₄, C₂H₆, C₂H₂) and hydrogen. Disadvantages of these methods are the high cost of production, due to the complexity of the apparatus, the length of time required by the process (tens of hours), as well as the limited size of the layers produced.

U.S. Pat. No. 3,829,544 [Hall] discloses a method for preparation of polycrystalline diamond composites by sintering particles of diamond at high temperature (around 2000° C.) and under high pressure (around 10 GPa). It is possible subsequently to infiltrate the porous diamond composites with copper, also by means of compression at high pressures and heating to obtain as a result a composite diamond-copper material [Pope et al, U.S. Pat. No. 4,104,344]. Values of 730-920 W/(m*K) are reached for the TC of the sintered polycrystals; for example a value of 920 W/(m*K) is reached using a mixture of synthetic diamonds of five different particle sizes in the range of 425-600 μm to 1-5 μm.

Diamond-copper composites can be prepared directly by applying heating and high pressure to a mixture of diamond particles and powdered copper. For example, by sintering synthetic diamonds of differing grain sizes, ranging from 7-10 μm to 425-600 μm, at 8 GPa and 1600-1800° C., materials with a TC of 240-900 W/(m*K) are obtained [Yekimov E. A., et al.//Inorganic Materials. 2008. V.44, N3. P. 275-281]. The manner of production of a diamond-copper composite by sintering at a high pressure is described by [Yoshida et al, U.S. Pat. No. 7,528,413]. A mixture of diamond and copper powders or a diamond powder and a copper plate are sealed in the molybdenum container under vacuum or in an inert atmosphere, and sintered at 1-6 GPa, 1100-1500° C. Sheets of IVB, VB Groups metals (Ti, Zr, Nb) are placed in a container to remove oxygen that otherwise would oxidize copper and reduce heat conductivity of a composite. The size of diamond particles is 5-100 μm, the content of nitrogen in diamond is 10-200 ppm, and a volume fraction of diamond in a composite is 60-90%. The density of a composite is 4.05-5.7 g/cm³, porosity is less than 0.5%, heat conductivity coefficient 510-1100 W/(m*K) increases with growth of the diamond particles size.

U.S. Pat. No. 4,902,652 [Kume et al] discloses a method for preparation of a diamond-carbide matrix composite. By means of physical vapor deposition (PVD)—plasma sputtering, vacuum evaporation, etc—coatings of transition metal (usually W), boron or silicon are applied in amounts of 0.1-30% (by volume); the coated diamond powder is then subjected to solid-phase sintering at high pressure and temperature. For example, diamond with a tungsten coating is sintered at 5.5 GPa and 1500° C. for 30 minutes, during which the reaction between the diamond core and the tungsten coating C+W→WC takes place, resulting in the formation of a composite of diamond particles with a matrix of tungsten carbide.

A disadvantage of the above described methods using compression under high pressures of more than 1 GPa, is the complexity of the apparatus required to implement these methods and certain limitations imposed by the method on the shape and dimensions of the products obtained thereby. For example, additional operation of plastic molding is needed to shape the products as necessary.

Typically, materials with high TC are produced as composite materials, in which both the filler and the matrix are substances with high TC. Composites with a diamond filler may be made using carbon, ceramic and metal matrices.

For example, a method is known of obtaining a polycrystalline diamond material with a TC of more than 1700 W/(m*K) using plasma-enhanced chemical vapor deposition of a diamond matrix into the pores of a preform of diamond particles, the particle size being typically around 100 μm [Herb et al, U.S. Pat. No. 5,273,790; Pinneo, U.S. Pat. No. 5,902,675]. The disadvantage of this method is the length of time the procedure requires (in the order of 100 hours), while the maximum thickness of the product is limited to 2-3 mm by the conditions of gas transport in the pores of the preform during chemical vapor infiltration (CVI).

Thus, the following general rules are observed when producing high TC composite materials:

the TC of a composite diminishes if

the volume part of the diamond filler diminishes, and/or

the content of impurities (especially nitrogen) in the diamond increases, and/or

particle size of the diamond filler decreases.

Among non-metallic nonelementary substances, those with maximal TC are cubic boron nitride, silicon carbide, and beryllium oxide. For monocrystals of c-BN, SiC and BeO, the coefficients of TC are 1300, 490 and 370 W/(m*K) respectively [High Thermal Conductivity Materials/S. L. Shinde, J. S. Goela (eds.). N.-Y.: Springer, 2006.]. BeO is not suitable for use because of its high toxicity. To produce the cubic form of boron nitride is just as complex technically as to produce synthetic diamond. Silicon carbide is used as a matrix in composites with diamond filler. For example, a means is known of obtaining a heat-conducting composite [Gordeev et al, RU 2206502], in which a porous preform is made out of diamond powder (by pressing, from slip with or without a bond). The preform is subjected to heat treatment to form a semi-finished item made of diamond particles bonded by non-diamond carbon (chemical deposition of pyrocarbon from the gaseous phase of hydrocarbons, carbonization of the bond or partial graphitization of the diamond under high-temperature processing in a vacuum or inert gas), followed by infiltration of liquid silicon to form silicon carbide by the reaction C+Si→SiC. With volume fractions of: diamond 50-85%, SiC 1-48%, Si 2-49%, the composites produced have a TC of 330-660 W/(m*K). By a small adjustment to this method, [Ekstrom et al, U.S. Pat. No. 6,914,025], composites with a TC of 340-730 W/(m*K) and a density of 3.2-3.4 g/cm³ can be produced. A disadvantage of this method is the high temperatures required at the stages of graphitization of the diamond (1200-1700° C.) and infiltration of the silicon (over 1400° C.). A fundamental problem with this means and in general with producing composites, which have non-metal matrices, is the complexity of ensuring high TC in the matrix, since the TC of ceramic materials falls sharply in the presence of impurities, defects and any deviation from a monocrystalline structure. For example, while the TC of monocrystalline SiC is 300-490 W/(m*K), for silicon carbide obtained by chemical vapor deposition it is 75-390 W/(m*K), for reaction-sintered SiC it is 70-190 W/(m*K), and for SiC produced by hot pressing it is 50-120 W/(m*K) [High Thermal Conductivity Materials/S. L. Shinde, J. S. Goela (eds.). N.-Y.: Springer, 2006.]. If the matrix does not have a sufficiently high TC, the composite will not achieve high TC either. But it is extremely difficult to obtain a monocrystalline ceramic matrix.

For composites based on a metallic matrix, silver and copper may be used, as these have thermal conductivities of 420 and 390 W/(m*K) respectively, the highest amongst metals. Copper is preferable, as silver is scarcer and more costly. As a cheap raw material, aluminium can be used, but at 230 W/(m*K), its TC is significantly lower. Aluminium is a carbide-forming element, although in the process of producing a composite, when liquid aluminium is in contact with diamond, carbide is produced only on the faces of the diamond crystals {100} [Ruch P. W., et al.//Compos. Sci. Technol. 2006. V.66, N15. P. 2677-2685]. Copper and silver are not carbide-forming elements; when molten they do not wet the surface of the carbon, and this is a fundamental problem in obtaining diamond-Cu and diamond-Ag composites. For these reasons, and also because diamond is a dielectric substance and conducts heat by means of phonons, whereas in metals, heat transfer is effected by electrons, it is difficult to achieve high adhesion and low thermal resistance at the matrix/filler interface. The problem is solved by creating a thin transitional carbide layer at the diamond-metal boundary, which is achieved either by introducing a small amount of a carbide-forming element into the metal of the matrix, or by prior applying a coating of a carbide-forming metal on the surface of the diamond.

In the first method, a carbide layer of the element introduced is formed around the diamond particles during the chemical interaction between the element and the diamond in the molten matrix metal.

For example, a method for infiltrating a molten alloy was developed by Weber and Tavangar. When copper was alloyed with additions of chromium or boron of increasing concentration, the coefficient of TC of the diamond-metal composite increased, peaking at a concentration of chromium to copper of 0.3% (at.), boron to copper of 2.5% (at.), and then decreased. With the concentration of diamond at 60% (vol.), and with a particle size of 200 μm, the TC of a diamond-Cr—Cu composite reached 600 W/(m*K), while that of a diamond-B—Cu composite reached 700 W/(m*K) [Weber L., Tavangar R.//Scr. Mater. 2007. V.57, N11. P. 988-991]. Using a eutectic alloy of Ag-3% (wt.) Si, a TC of 775-860 W/(m*K) was obtained for composites with monodisperse diamond fillers in which the particle sizes were 350 and 450 μm and the proportion by volume of diamond in the composite was 61-65%. For bidisperse fillers where the diamond particle sizes were 450 and 52 μm or 350 and 52 μm and the percentage by volume of diamond was 73-76%, the TC achieved was 960-970 W/(m*K) [Weber L., Tavangar R.//Adv. Mater. Res. 2009. V.59. P. 111-115]. In both cases, infiltration of the molten metal into the densely packed layer of diamond was effected by gas pressure assisted infiltration: the heating and the isothermic holding took place in a vacuum at 10 Pa, and before cooling, inert gas (Ar) was introduced at 0.5-5 MPa. A disadvantage of this method is the length of time required by the process: the slow rate of 200-500° C./h at which the temperature is raised to the melting point of the matrix and the length of time taken—30-40 min—for infiltration by the molten matrix to take place. It is due to long time of carbide-former element diffusion from molten alloy to diamond surface and carbide growth. It shall be noted, that this method is applicable to those carbide-forming elements only, which are soluble in metal of a matrix (form an alloy with metal of a matrix): for example, use W and Mo for a copper or silver matrix is impossible.

Infiltration from eutectic alloys on the basis of Cu, Ag, Au with the lowered melting temperature, containing carbide-forming additives Si, Y, Sc, La is described in [Ludtke et al, US PA 20060157884]. Synthetic or natural diamond with 5-300 μm particles is used as filler. The layer of silicon, yttrium or rare earth metal carbide is formed on a surface of diamond by interaction with the melt. For diamonds of particle sizes 40-80 μm and 80-150 μm composites with heat conductivity 410-500 W/(m*K) are obtained by infiltrating at 860-900° C. eutectic alloys of Ag-11% (at.) Si or Cu-9.3% (at.) Y, with or without the aid of pressure. The disadvantage of this method is the use of alloys of readily oxidized rare-earth metals, which are usually commercially available as oxides (while scandium is rather expensive).

In [Nishibayashi, U.S. Pat. No. 6,031,285], various alternatives are discussed for preparation of a metal-diamond composite for heat sinks by means of infiltration or sintering of powders while heating in a vacuum or under pressure, using alloy containing a carbide-forming element (usually titanium) melted together with, or separately from, the basic metal of the matrix (usually a Cu—Ag alloy with a silver content, in atomic proportions, of not less than 0.6 or a copper content of not less than 0.8). Particles of diamond, measuring 60-700 μm (usually 200-300 μm) serve as the filler. With a volume fraction of diamond of around 50%, the maximal value for the TC of the composite is approximately 700 W/(m*K). In a continuation [Nishibayashi, U.S. Pat. No. 6,171,691], a preferred method is shown to be infiltration, when the alloy with the lower melting point, containing the carbide-forming element (proportion by mass Ti 0.1-8%, for example an alloy with an atomic composition of 0.7 Ag-0.28 Cu-0.02 Ti), is melted first to form titanium carbide on the surface of the diamond C+Ti→TiC. The remainder of this metal is then evaporated, after which the basic metal of the matrix is melted (Ag, Cu or Al). The maximal value of TC is 900 W/(m*K), for diamonds with a particle size of 300-700 μm in a silver matrix. The disadvantages of this method are connected with multistage character of the process. The presence of evaporation stage requires the use of special equipment, such as a trap and a cooler; to collect the evaporated metal (to condense it) that complicates the installation structurally and demands additional power inputs. Besides, the by-product is collected as the alloy, which is depleted by a carbide-forming element. This by-product can be reused only upon regeneration, which includes:

analysis of the content of a carbide-forming element in the alloy;

dissolution of the required quantity of a carbide-forming element in the melt of this alloy.

The necessity of a regeneration step strongly complicates the process and increases its cost otherwise the process results in formation of waste.

In general, the use of special alloys of copper or silver with carbide-forming elements for infiltration has disadvantage, since these alloys are less accessible and more costly than copper or silver alone. To avoid use of such alloys, another approach has been proposed to apply onto diamond particles a coating of a carbide-forming element before obtaining a composite.

Thus, [Chen et al, U.S. Pat. No. 5,096,465] discloses a diamond-metal composite useful for manufacturing of tools, wherein the composite is obtained from diamond particles 50-2000 μm in size, with a metal coating 0.5-30 μm thick, in a matrix made from an alloy based on Ni, Co, Fe, Al, Sn or Cu, by means of hot pressing at 650-1300° C., 7-140 MPa, for 1-6 minutes in air in a graphite mold. Coatings may consist of one to three layers of NiB, W, Ta, Mo, V, Cr, Cu, Sn, Co, Fe, Pd, Pt. The volume part of the filler in the composite is 40-75%. However, the proposed method is inapplicable to manufacturing composites with high TC since the obtained composites are characterized by high thermal resistance on a filler/matrix interface due to formation of low thermally conductive metal carbides and high thickness of coatings, and generally low TC of the matrix.

A similar approach is taught by [Colella et al, U.S. Pat. No. 5,783,316 & U.S. Pat. No. 6,264,882], where a method for manufacturing a diamond-metal composite having a TC not less than 400 W/(m*K), is disclosed using as a filler diamond particles having the size of 1 to 100 μm, wherein the particles are coated with a thin inner layer of 0.01-1 μm thickness of a carbide-forming metal (W, Cr, Re, Zr, Ti) and a thick outer layer of 0.1-10 μm thickness of binding metal (Cu, Ag or a copper-silver alloy). The inner coating may be applied by magnetron sputtering in a vibrating bed (as described in U.S. Pat. No. 5,783,316 or U.S. Pat. No. 6,264,882), as well as by chemical or physical vapor deposition. The diamond powder with the double-layered coating is compacted under a pressure of 14 MPa. Then, the matrix is impregnated by capillary infiltration of a metal into the porous compact in a vacuum, the process involving brief heating (up to 30 seconds) to a temperature slightly (2-20° C.) higher than the melting point of the matrix.

However, as for the property of composites obtained by the method disclosed by Colella et al in U.S. Pat. No. 5,783,316 and U.S. Pat. No. 6,264,882, no particular example data on the coefficient of TC is presented in these patents except for the lower limit declared by the inventors. It shall be noted also that the process of its manufacturing includes several steps using different coating techniques (such as “wet” coating after gas-phase deposition) and involving various complex equipment and is economically inefficient. Further, the infiltration stage requires special furnaces with precision control of temperature to provide fast uniform heating of the preform as temperature rises in step-wise mode. Limited infiltration time can also hinder the possibility to obtain products of large sizes of any configuration due restrictions implied by finite velocity of impregnation.

Thus, there is a need in a high thermally conductive material useful, for example, in semiconductor heat sinks, which can be manufactured by economical and reliable process avoiding the above described disadvantages of the prior art methods.

### BRIEF SUMMARY OF THE INVENTION

Accordingly, the object of the present invention is to provide high thermally conductive diamond-metal composites avoiding the drawbacks connected with high thermal resistance on diamond/metal matrix interface, whilst providing at the same time high adhesion of the metal to the diamond particles, and an economically efficient method of manufacturing thereof.

The above object of the invention is achieved by prior applying a single-layered continuous high surface area coating of carbide-forming element onto the diamond filler particles with subsequent step of infiltration, without a step of applying the second additional layer-solder of the metal alloyed with a matrix metal (commonly, a metal identical to the metal of the matrix), wherein the composition, thickness and properties of the coating are selected in predetermined ranges. The research carefully performed by the inventor of the present invention enabled to find a combination of the above mentioned technical features, which, being controlled in a predetermined narrow range, provide the achievement of the technical effect of the invention.

In particular, the high thermally conductive diamond-metal composite having the desired properties can be obtained, on one hand, by controlling parameters of a coating, including its composition, structure and properties (such as element and phase composition, thickness and roughness); and, on the other hand, by using particular conditions when performing method steps, including, conditions of melt infiltration of a metal matrix into a bed of coated filler particles (such as pressure).

The invention is based on the finding that the required bonding of the matrix metal to the diamond particles with formation of the high thermally conductive diamond-metal composite can be achieved either by pressureless infiltration of the matrix metal into the dense bed of diamond particles preliminary coated with a single-layered, continuous, high surface area, 30 to 500 nm thickness h, and not less than 20 nm roughness Ra coating of a metal and/or carbide of a carbide-forming element selected from IV-VI Groups of the Periodic Table, preferably, tungsten, molybdenum, or, alternatively, by pressure-assisted infiltration of the matrix metal into the dense bed of diamond particles preliminary coated with a single-layered, continuous 5 to 500 nm thickness coating of metal and/or carbide of a carbide-forming element selected from IV-VI Groups of the Periodic Table, including W, Mo, Cr, Ti, Zr, Nb, Ta including any combinations thereof.

### DETAILED DESCRIPTION OF THE INVENTION

### Definitions

As used herein, the term “high thermally conductive” relates to any material that has a coefficient of TC higher than 500 W/(m*K).

The expression “a metal of an element selected from IV-VI Groups of the Periodic Table” encompasses metals and metal alloys of an element or elements selected from IV-VI Groups of the Periodic Table.

The expression “a carbide of an element selected from IV-VI Groups of the Periodic Table” encompasses carbides of stochiometric composition, such as semicarbides, monocarbides etc and carbides of non-stochiometric composition.

The expression “an element-containing coating” further means a coating of metal and/or carbide of this chemical element, and also a coating of metal and/or carbide of this element which can possibly contain additionally up to about 10% (at.) of at least one other element, which can be introduced either together with the basic element or in the course of a separate process step.

The expression “a single-layered coating” means an element-containing coating applied on a diamond in a single process, i.e. using single technology. “A single-layered coating” can have a mono-component composition, when it is composed of one substance, e.g. a single metal or single carbide, or alternatively, a multicomponent composition as result of carbidization of the coating—reactions of carbide-forming element of a coating with diamond carbon of a substrate. For example, for tungsten-containing coating the following reactions are possible:

2W+C_{diamond}=W₂C (1)

W+C_{diamond}=WC (2)

W₂C+C_{diamond}=2WC (3)

Further, the expression “forming a coating on diamond particles” encompasses both direct applying a coating of a metal onto the diamond particles, as well as subsequent conversion of a metal in the coating to the carbide thereof as result of heating coated diamond particles in the process of infiltration. The processes suitable for applying a coating are listed below in the detailed description of the invention. Other suitable processes of coating known from the available prior art can be also used.

Throughout the present description, by the term “thickness”, weight-average thickness h is meant as a measure of the coating quantity. Weight-average thickness h is calculated as a volume of a coating, divided by the area of an ideal smooth surface covered by this coating.

Further, as used herein, the term “roughness” relates to an average (arithmetic-mean) roughness Ra, as characteristics of the structure of a coating, i.e. a measure of deviations from ideally smooth surface. The average roughness Ra is measured as average value of absolute deviations of a profile from a baseline [ISO 4287:1997 “Geometrical Product Specifications (GPS)—Surface texture: Profile Method—Terms, Definitions and Surface Texture Parameters”; ANSI/ASME B46.1-2002 “Surface Texture (Surface Roughness, Waviness and Lay)”].

Further, as used herein the term “high surface area” with respect to the coating means the surface area of the coating is substantially higher than the surface area of an initial uncoated diamond. The surface area of the coating can be measured e.g. by atomic force microscopy (AFM) or any other suitable method known to a specialist in the art. The area and roughness of a surface are interconnected: usually, the higher the roughness, the higher the surface area.

Further, as used herein the expression “interface of high surface area” means that the surface area of coating/matrix interface in the obtained composite substantially exceeds the surface area of the diamond particles before applying a coating.

As used herein, “a”, “an”, and “the” can mean singular or plural (i.e., can mean one or more) unless indicated otherwise. Unless the context requires otherwise or specifically stated to the contrary, integers, elements or steps of the invention recited herein as singular integers, steps or elements clearly encompass both singular and plural forms of the recited integers, steps or elements.

Throughout this specification, unless the context requires otherwise, the word “comprise”, or variations such as “comprises” or “comprising”, will be understood to imply the inclusion of a stated step or element or integer or group of steps or elements or integers but not the exclusion of any other step or element or integer or group of elements or integers.

Unless specifically stated otherwise, each feature described herein with reference to a particular aspect or embodiment of the invention shall be taken to apply mutatis mutandis to each and every other aspect or embodiment of the invention. For example, any one or more features described herein with respect to composites according to the invention shall apply to those embodiments relating to methods and vice versa.

Thus, according to the invention in its most general definition, a diamond-metal composite is provided, having a TC above 500 W/(m*K), comprising coated diamond particles embedded in a metal matrix having a TC of not less than 300 W/(m*K), wherein the particles are coated with a continuous single-layered coating of a metal and/or carbide of an element selected from IV-VI Groups of the Periodic Table, the coating having a thickness h of less than 500 nm and a certain surface texture, and wherein the metal of the matrix fixedly binds to the coated diamond particles.

In one aspect of the invention, a diamond-metal composite having a TC above 500 W/(m*K) comprises coated diamond particles embedded in a metal matrix having a TC of not less than 300 W/(m*K), wherein the particles are coated with a continuous high surface area single-layered coating comprising at least one of tungsten (W), tungsten semicarbide (W₂C), tungsten monocarbide (WC), wherein the coating has a thickness of 30 to 500 nm and a surface roughness Ra not less than 20 nm, and wherein the metal of matrix fixedly binds to the coated diamond particles by forming an interface of the high surface area.

According to the invention, the roughness of the coating can be increased with the coating thickness, i.e. the thicker the coating, the higher the roughness can be provided, and respectively the higher the interface specific surface area can be achieved, and hence, the better is the adhesion and the higher is the thermal conductance on the coating/matrix interface. However, it shall be kept in mind that though on one hand, the thickness and roughness of the coating shall be sufficient to provide the wettability of the diamond particle by a matrix metal to form an adherent bond with the coating, on the other hand, the thickness and roughness of the coating shall not be too high to deteriorate the TC. The detailed theory describing the mechanism of heat transport in a composite, including phenomena of electron-phonon and phonon-phonon coupling in transition regions (such as a boundary layer of diamond filler, an intermediate layer of coating material, a boundary layer of metal matrix), is currently under development, see, for example, [Battabyal M., et al//Diamond Relat. Mater. 2008. V.17, N7-10. P. 1438-1442]. Therefore, currently, it is impossible to calculate apriori the features that would guarantee the high TC of the composite. Since the only means of accessing these parameters could be semi-quantity estimations, experimental investigations in this area have major importance.

As result of the research performed by the inventor, it has been found that the coating shall have a thickness h of 30 to 500 nm, preferably 100-300 nm for spontaneous pressureless infiltration of metal matrix, and in addition, the coating shall have a surface roughness, specifically Ra at least 20 nm, to reduce the thermal resistance of the interface. The upper extremity of value of a coating surface roughness is limited by the necessity of maintaining the coating continuity (Ra/h<1 for a case of a substrate with a zero roughness). Typically Ra/h ratio can make 0.1-0.3 for coating thickness above 100 nm (see Examples), so for coating thickness of 500 nm its average roughness can reach ≈100 nm. These parameters provide good wettability of coated filler by liquid metal and low residual porosity (less than 5%) of products and thus, result in diamond-copper composites of high TC that can be obtained by pressureless infiltration. Wetting by metal of a matrix of all the surface of a coating during infiltration is provided, i.e. a coating/matrix interface is formed on all the surface of a coating, including ledges, hollows, and others features of a relief (texture). At the same time, coatings do not contain pores which are not filled with metal of a matrix at pressureless infiltration.

The interface between a metal matrix and a layer of coating of a carbide-forming element bonded with diamond is formed directly during infiltration process. Owing to long enough holding (on the average 3-7 min) at infiltration temperature (900-1200° C.), the transition region including a coating, diamond/coating interface and coating/matrix interface, and also a composite as a whole are thermally stable at enhanced temperatures, up to close to fusion temperature of a matrix. As substances of a coating and a matrix (e.g. W and Cu) are mutually not soluble, a well-defined coating/matrix interface is formed. In this case impurities do not migrate (not diffuse) from a coating to a matrix material, which impurities otherwise could reduce heat conductivity of a matrix and a composite as a whole.

In another aspect of the invention, it has been found that the coating shall have a thickness h of 5 to 500 nm, preferably from 5 to 100 nm and a certain surface texture, to enable pressure-assisted infiltration of metal matrix at a pressure of 0.1 to 100 MPa, with the achievement of low residual porosity (less than 5%) of products and preparation of diamond-copper composites of high TC.

According to the invention, a tungsten-containing layer provides especially good wetting of the particles with the matrix metal and result in diamond-metal composites of high TC.

In one example embodiment of the invention according to the first aspect of the invention, the said metal or metal alloy is selected from copper, silver and copper-silver alloys.

In one example embodiment according to the first aspect of the invention, the diamond particles are monocrystals.

In one example embodiment of the first aspect of the invention, a monodisperse diamond powder is used, with particles of approximately equal size. A size of diamond particles lays, as a rule, in the range of 50 to 1000 μm, preferably, from 100 to 700 μm, more preferably, from 150 to 400 μm. Diamond particles of other sizes can be also added, so a polydisperse mixture of particles can be used, when smaller particles fill in the gaps between larger particles, to increase the volume fraction of diamond in composite, as well known for a specialist and described in the art.

In one example embodiment of the invention according to the first aspect of the invention, a carbide-forming element is tungsten, and the coating can comprise metallic tungsten W and/or tungsten carbides selected from W₂C, WC, wherein both alternatives are possible including the situation when a multi-phase coating is formed on a single diamond particle/grain, as well as a mixture of diamond particles/grains is formed including different grains coated with coatings having different composition. Any combination selected from combinations W—W₂C—WC, W—W₂C, W—WC, W₂C—WC can be formed. Carbides of non-stochiometric composition, for example WCₓ, where 0<x<1, can be also present in the coating.

In another example embodiment of the invention according to the first aspect, the carbide-forming element is molybdenum, and the coating comprises metallic molybdenum (Mo) and/or molybdenum carbides (Mo₂C, MoC), and additionally, 0.1-10% (at.) of at least one element selected from B, Co, Cr, Fe, Hf, La, Mn, Mo, Nb, Ni, Pd, Pt, Re, Si, Ta, Ti, V, W, Y, Zr.

According to the above described particular embodiments, the high thermal diamond-metal conductivity composite can be obtained by pressureless infiltration.

In one particular example embodiment of the invention according to the first aspect, a diamond-metal composite having a TC above 500 W/(m*K) is provided, wherein the composite comprises diamond particles embedded in a copper matrix, wherein the particles are coated with a continuous high surface area tungsten-containing coating having a thickness h of 30 to 500 nm and a surface roughness Ra not less than 20 nm, and further comprising 0.1-10% (at.) of at least one element selected from B, Co, Cr, Fe, Hf, La, Mn, Mo, Nb, Ni, Pd, Pt, Re, Si, Ta, Ti, V, W, Y, Zr.

Thus, for example, in case the base carbide-forming element is W, the coating can comprise additional carbide-forming element Mo.

In presented Examples of the invention, a diamond-metal composite having a TC of up to 740 W/(m*K) and 910 W/(m*K) is provided, wherein the composite comprises diamond particles such as monodisperse diamond filler, embedded in a copper matrix, wherein the particles having mean size of 180 μm and 430 μm accordingly are coated with a continuous single-layered tungsten-containing coating having a thickness h of 30 to 500 nm and a surface roughness Ra at least 20 nm.

Preferably, a method of manufacturing a diamond-metal composite according to the first aspect of the invention comprises the step of pressureless infiltration.

In a second aspect of the invention, a diamond-metal composite having a TC above 500 W/(m*K) is provided, wherein the composite comprises coated diamond particles embedded in a copper matrix, wherein the particles are coated with a continuous surface textured coating on the basis of an element selected from the elements of groups IV-VI of the Periodic Table, including W, Mo, Cr, Ti, Zr, Nb, Ta, the coating having a thickness h of 5 to 500 nm, preferably, 5 to 100 nm, and wherein the metal of the matrix fixedly binds to the coated diamond particles.

Preferably, according to the second aspect of the invention, the said coating comprises metal and/or carbide of W or Mo.

Optionally, according to the second aspect of the invention, the coating further comprises 0.1-10% (at.) of at least one other element selected from B, Co, Cr, Fe, Hf, La, Mn, Mo, Nb, Ni, Pd, Pt, Re, Si, Ta, Ti, V, W, Y, Zr.

Preferably, a method of manufacturing a diamond-metal composite according to the second aspect of the invention comprises the step of infiltration under pressure of 0.1-100 MPa.

In still another aspect of the invention, a diamond-metal heat sink for mounting a semiconductor chip is provided, comprising a diamond-metal composite according to the first or the second aspects of the invention.

The diamond-metal composite can be finished by electrical discharge machining (EDM), laser cutting, plastic deformation, plating, grinding or polishing to obtain a finished substrate to be used in a heat sink. The surface of a composite can be plated with an additional layer of metal of a matrix (Cu, Ag). Without plating or after plating the surface can be treated by methods of dry or wet abrasive machining (grinding etc.), polishing to provide low roughness Ra˜1 μm. Further the surface of a compact from a composite material can be plated entirely or partially by one or more layer of a metal selected from e.g. Ta, Ni, Au, Pt, In, Sn to provide a coating having barrier, protective, brazing or some other function.

In still another aspect of the invention, an article of manufacture for use in semiconductor or vacuum tube electronic devices is provided, comprising a diamond-metal composite according to the present invention, wherein the article is a heat sink.

In one aspect, the diamond-metal composite can be used as a substrate, support for mounting a semiconductor device, such as central processing unit (CPU), insulated gate bipolar transistor (IGBT), laser diode. The semiconductor device can be jointed with the diamond-metal composite by soldering, adhesive bond or using any other suitable means of securely fixing.

In one aspect, the diamond-metal composite can be used in vacuum tube devices, such as X-ray tubes, as substrate or support for target-anode, being bombarded by electron flux. The target in the form of thick film or layer can be applied onto the substrate by sputtering or another means. For example, a copper layer of 10-1000 μm thickness can be applied onto the copper-diamond composite heat sink for manufacturing of X-ray tube with copper anode. Alternatively, a target in the form of material item can be jointed with the diamond-metal composite with the aid of diffusion welding or another method.

In still another aspect of the invention, an article of manufacture for use in electronic devices is provided, comprising a diamond-metal composite according to the present invention, wherein the article is a heat spreader.

In still another aspect of the invention, a heat exchanger unit for a electronic device is provided, comprising an article of manufacture made of a composite material according to the invention, wherein the said article is finished by electrical discharge machining (EDM), laser cutting, plastic deformation, plating, grinding or polishing.

In one aspect, the article made of diamond-metal composite and operating as heat sink has channel or channels for circulation of cooling medium (liquid or gaseous).

In still another aspect of the invention, a method for manufacturing a composite material comprising a metallic matrix embedded with coated diamond particles according to the first aspect of the invention is provided, the method comprising the steps of:

coating the said diamond particles with a continuous single-layered coating comprising a metal and/or metal carbide of a carbide-forming element of Groups IV-VI of the Periodic Table, the coating having a thickness h of 30 to 500 nm and a surface roughness Ra not less than 20 nm,

providing a Group IB of Periodic table metal or metal alloy having a TC of not less than 300 W/(m*K), and infiltrating the said metal or metal alloy in the molten form into the dense bed of coated diamond particles.

This aspect of the invention is further characterized by the features specified above for the other aspects of the invention.

In a particular example embodiment of a method of manufacturing a diamond-metal composite according to the present invention, a coating is deposited by a process selected from chemical vapor deposition (CVD), physical vapor deposition (PVD), interaction with reactant substance in a salt melt bath, co-sintering by applying fine particles of reactant substance on the surface of diamond particles with subsequent heat treatment, diffusion coating by reaction between diamond particles and a powder of a reactant substance or a mixture of reactant substances.

According to the present invention, the step of infiltration is carried out in a vacuum or non-oxidizing atmosphere, such as in hydrogen or inert gas.

In one example embodiment of the present invention, the step of infiltration is carried out at a temperature of 900 to 1200° C., preferably 980-1130° C.

According to one example embodiment of the present invention, the step of infiltration is carried out in a pressureless process.

According to another example embodiment of the present invention, the step of infiltration is carried out with the aid of pressure of 0.1-100 MPa.

According to the present invention, the method provides manufacturing a diamond-metal composite material having the TC higher than 500 W/(m*K).

In a particular example embodiment of a method for manufacturing a diamond-metal composite according to the first aspect of the present invention, the method comprises the steps of:

coating the said diamond particles with a continuous tungsten-containing coating having a weight-average thickness in the range of 30 to 500 nm and a surface roughness Ra not less than 20 nm,

providing copper or silver or copper-silver alloy, and

infiltrating the said copper or silver or copper-silver alloy in the molten form into the packed bed of coated diamond particles, in a pressureless process.

The obtained composite has the TC more than 500 W/(m*K) for monodisperse filler (e.g. from 540 to 910 W/(m*K) according to the presented Examples).

In a particular example embodiment of a method for manufacturing a diamond-metal composite according to the second aspect of the present invention, the method comprises the steps of:

coating the said diamond particles with a continuous tungsten-containing or molybdenum-containing coating having a thickness in the range of 5 to 500 nm,

providing copper or silver or copper-silver alloy, and

infiltrating the said copper or silver or copper-silver alloy in the molten form into the packed layer of coated diamond particles with the aid of pressure of 0.1-100 MPa.

The obtained composite has the TC of more than 500 W/(m*K) for monodisperse filler.

In another example embodiment of a method for manufacturing a diamond-metal composite according to the present invention further comprises a step of final treatment of the obtained diamond-metal composite by electrical discharge machining (EDM), laser cutting, plastic deformation, plating, grinding or polishing.

According to one of the preferred embodiments of a method according to the present invention, particles of diamond are first coated with a thin tungsten-containing layer.

The filler of coated diamond particles is placed in a mold to form a densely packed bed; on top is placed the metal of matrix—copper, silver or a copper-silver alloy. The metal is then infiltrated into the layer of filler by heating above the melting point of the matrix in the temperature range 900-1200° C., the maximum temperature being held for a period of 1-15 minutes. The process is carried out in a vacuum or in an inert or reducing gas (hydrogen).

To achieve a high TC, high-quality synthetic diamond with a low content of impurities is used as a starting material, the individual particles of which has facets and are monocrystals. Technical natural diamond can be used as a starting material as well. If a monodisperse filler is used, diamond with a particle size ranging from 50 to 1000 μm is selected, mainly 100-700 μm, preferably 150-400 μm. For diamond particles smaller than 50-100 μm, a diamond-metal boundary having thermal resistance expands considerably in composite, with a corresponding fall in the TC of the composite as a whole. Diamond with a particle size of more than 700 μm is hard to source; in addition, if one of the linear dimensions of the product is several millimeters, too large a particle size in the filler leads to heterogeneity of the composite on this scale, especially on the surface (a surplus of the matrix material or roughness). Generally, for large-scale composite articles the size of diamond inclusions in matrix can be more than 1000 μm: so, for example, monocrystals of diamond having the size of 2 mm and above can be used. If monodisperse filler is used, the volume fraction of diamond in the composite is 60-63%. To obtain a composite with a higher volume percentage of diamond and, consequently, a higher TC, polydisperse mixtures made up of diamond particles with different grain size distributions may be used.

Tungsten is preferably used for the basis of coating, since both metallic tungsten and tungsten carbides are wetted well by the matrix metal (Cu, Ag), allowing spontaneous infiltration by the liquid matrix to be effected in a short time without the need for external pressure (mechanical or gas). On the other hand, tungsten and its carbide are not dissolved in and do not react chemically with liquid copper or silver. In addition, tungsten and tungsten carbide have a sufficiently high TC. Amongst metals, tungsten has a TC 170 W/(m*K) next to that of aluminium. Both carbides of tungsten, W₂C and WC have a TC as high as, or higher than, most other elements (TiC, ZrC, B₄C, Cr₃C₂, MoC, Mo₂C etc.). Variations may be made in the composition of the coating from tungsten W to tungsten monocarbide WC, including a multi-phase coating W—W₂C—WC. At a temperature of more than 900° C., the diamond reacts chemically with the tungsten coating, so that the coating gradually becomes carbide.

The tungsten-containing coating may be applied on diamond by various methods, including:
chemical vapor deposition, for example from tungsten fluoride [Wilder et al, U.S. Pat. No. 3,871,840] or from tungsten carbonyl [Genvarskaya et al, SU 414052];
physical vapor deposition, for example by magnetron sputtering [Berov et al, RU 2090648];
deposition from a salt melt [Oki et al, U.S. Pat. No. 5,090,969];
co-sintering, i.e. applying fine particles of reactant substance on the surface of diamond particles and the further heat treatment with occurrence of solid-solid reactions (see, for example, [Fokina et al, RU 2149217]);
diffusion method, i.e. carrying out reactions of diamond particles with a powder of reactant substance (see, for example, [Volk et al, SU 526678], [Baldoni et al, U.S. Pat. No. 6,663,682]).

The thickness h of the coating is 30-500 nm, preferably 100-300 nm for pressureless infiltration of metal matrix. With a thinner coating (less than 30 nm), the particle with the coating is wetted poorly with the molten matrix metal and the composite either does not succeeded in obtaining, or is of inferior quality (there will be defects in the shape of the product, individual grains breakoff from the surface). As the thickness of the coating increases, the cost of applying the coating increases, making a coating thicker than 500 nm undesirable.

Usually, TC of a composite decreases with coating thickness (see Examples 3, 7, 8 for SDB 1085 diamond: the composite TC decreases from 910 down to 580 W/(m K) when h increases from 110 to 320 nm). However, a case is possible, when TC of a composite varies only slightly with the coating thickness (see Examples 9, 10, 11 for AS-160 diamond: a composite TC is 660-740 W/(m K) in a range h=130-290 nm). The second case can be explained by an increase in the size of the coating crystallites (grains) with the increase in coating thickness. The size effect, when TC of a solid increases with growth of size L of its crystals, including TC growth linearly with the size L of crystal is known [Berman R. Thermal conduction of solids. Oxford: Clarendon Press, 1976]. Thermal resistance of a coating layer R, (m²*K)/W on the diamond-metal boundary is described by the formula

$$R = \frac{h}{{λ}_{i}} \qquad ( 4 )$$

where λᵢ is the TC of a coating; h is the thickness of a coating. If the size L of coating crystallites increases proportionally to thickness of a coating (L˜h), and TC of a coating λᵢ increases proportionally to the crystallites size owing to the size effect (λᵢ˜L), then, according to the formula (4) the interface thermal resistance R of a composite will remain constant. Accordingly TC of a composite as a whole remains approximately constant. In the first case TC of a coating λᵢ does not change with coating thickness h (the size L of coating crystallites remains constant), accordingly, eq. (4) shows that the thermal resistance of boundary R grows proportionally to h, and, as a result TC of a composite decreases with coating thickness h.

Thus, another factor that could influence the resulting TC of the composite material is the size of the coating crystallites (grains) L.

In case of metal matrix infiltration with the aid of pressure the thickness of a coating can be less—down to 5 nanometers. As matrix metals, the following metals and alloys of sufficient purity may be used: oxygen-free electronic copper; commercially pure silver (weight content of the basic substance—Cu or Ag—99.9% or above); copper-silver alloy (72% wt. Ag, 28% wt. Cu).

Molds for the process are preferably made of graphite, which will not be wetted by the molten metal of the matrix; other materials may also be used (for example, quartz glass). Molds with the matrix-filler blank may be heated directly or indirectly, using resistive or induction heating. The maximal working temperature is less than 1200° C., which allows the process to be carried out in air in a heat-resistant chromium-nickel steel chamber, whose walls are heated by an induction current. This method allows swift heating, the possibility of rapid cooling a short time after infiltration and a fairly simple arrangement of apparatus. At the temperatures at which infiltration takes place, oxygen may oxidize the diamond, the coating and the metal of the matrix, and so the process is carried out in a vacuum or in an inert or reducing atmosphere.

In the model of the porous media consisting of identical spherical solid particles of diameter D, velocity of capillary infiltration of liquid is described by the known equation

$$l = {( \frac{γ \cdot cos θ}{15 μ} \cdot \frac{ɛ \cdot D}{1 - ɛ} \cdot t )}^{1 / 2} \qquad ( 5 )$$

where l, m=the distance which has been passed by front of a liquid; y, N/m=surface tension of a liquid on a liquid-gas boundary; θ=wetting angle of a solid by a liquid; p, Pa*s=dynamic viscosity of a liquid; ∈=porosity of the solid media (a volume void fraction); t, s=time. The equation (5) is deduced from assumptions about the viscous mode of a liquid flow according to Darcy law when permeability is described by the Kozeny-Carman equation, and influence of gravitation can be neglected (capillary pressure p_{c}, calculated on the equation (6) considerably exceeds value of a hydrostatic pressure p_{g}, calculated on the equation (7)).

$$\begin{matrix}{p}_{c} = γ \cdot cos θ \cdot \frac{6 ( 1 - ɛ )}{D \cdot ɛ} & ( 6 ) \\ {p}_{g} = ρ \cdot g \cdot h & ( 7 )\end{matrix}$$

where ρ, kg/m³=density of a liquid; g=9.81 m/s²=gravitational acceleration; h, m=height of a column of a liquid.

For a copper melt near the melting point 1084° C. the surface tension is 1.35 N/m, density is 8.03 g/cm³. The wetting angle of tungsten or tungsten carbide by copper is small (cos θ≈1). At values ∈≈0.4, D=200-500 μm and h<5 cm which are typical for described process, we have p_{c}>>p_{g}. It is obviously from the equation (5), that the infiltration velocity l/t increases in case more coarse filler is used, with respective increase of D and accordingly, the pore size. Infiltration velocity also rises with reduction of melt viscosity, that takes place at increase in melt temperature.

According to the present invention, a step of pressureless infiltration can be performed at a temperature of 900-1200° C., preferably 980-1130° C. The holding time at the maximal temperature is 1-15 min, preferably 3-7 min. If the holding time is too short, the melt does not sufficiently impregnate a bed of filler particles to obtain a high TC diamond-metal composite. The viscosity of liquid metal decreases as the melt temperature raises, thus if the maximal temperature of the process insufficiently exceeds the melting temperature of the metal, the process of infiltration does not occur at all or runs unacceptably slow. Contrary, if the infiltration temperature is too high, undesirable effects can occur, such as increase in porosity of a composite, evaporation of metal of a matrix, or the increase of a thermal loading of the chamber.

### DETAILED DESCRIPTION OF PARTICULAR EMBODIMENTS OF THE INVENTION

In the examples presented, the density of the composite samples was measured by a pycnometer method with 1% accuracy, and the TC was measured using the steady-state axial heat flux method with 7% accuracy at 60-70° C. temperature. The average coefficient of linear thermal expansion (CTE) in a range from 20 to 300° C. was measured on a dilatometer with accuracy 5%. The longitudinal velocity of a sound V_{L} in samples of composites was measured at frequency of 5 MHz. The composition of the coating was determined by X-ray diffraction. The density of the ideal non-porous composite was calculated according to the equation:

$${ρ}^{*} = \frac{1 + C}{\frac{( 1 - x )}{{ρ}_{d}} + \frac{x}{{ρ}_{c}} + \frac{C}{{ρ}_{m}}} \qquad ( 8 )$$

where C=the ratio of the mass of the matrix (metal) to the mass of the filler (coated diamond); x=the mass fraction of the coating on the diamond, p_{d}=3.52 g/cm³=the density of the diamond, p_{c}=19.3 g/cm³=the density of the coating (W); pₘ=the density of the matrix metal. According to observations with an optical microscope, the composite samples had no open porosity (examples 3, 6-16). The closed porosity of the composite E was calculated by means of the equation

$$ɛ = 1 - \frac{ρ}{{ρ}^{*}} \qquad ( 9 )$$

where p=the pycnometric density of the sample. The volumetric fraction of diamond θ_{d} in the composite was

$${θ}_{d} = \frac{1 - x}{1 + C} \cdot \frac{ρ}{{ρ}_{d}} \qquad ( 10 )$$

The weight-average thickness of the coating h was calculated according to the formula

$$h = \frac{x}{{ρ}_{c} s} \qquad ( 11 )$$

where s=6/(p_{d}Dφ) is the specific geometric surface of the diamond powder; D is the average size of the diamond particles; φ=0.7 is the form factor. Measurements of the local thickness of the coating on individual particles of diamond on 30×30 μm area using electron-probe micro-X-ray spectral analysis on a scanning electron microscope gave results corresponding to those arrived at by the calculation of h with deviations within the limits of up to ±20%. Arithmetic mean roughness Ra of particles facets was measured by scanning 30×30 μm surface area of grains on atomic force microscope for initial diamond and diamond with the coating.

### EXAMPLES

### Example 1

0.35 g of each of the following powders having a particle size of 160-315 μm, was poured into graphite molds having 6 mm in diameter:

original diamond;

diamond with a 220 nm thick coating of titanium carbide;

diamond with a 170 nm thick coating composed of chromium carbide and chromium;

diamond with a 130 nm thick coating composed of molybdenum carbide and molybdenum;

diamond with a 110 nm thick coating composed of tungsten carbide and tungsten;

diamond with a 480 nm thick coating composed of tungsten carbide and tungsten.

A portion of 0.5 g of copper was placed on top of the bed of particles in each mold. The molds were placed in a chamber, 22 mm in diameter, made of quartz glass, which was placed in a cylindrical furnace heated by resistive heating. The chamber with the molds was kept at a constant flow of hydrogen, at atmospheric pressure, while being heated over a period of 20 minutes to reach a temperature of 1120° C. This temperature was maintained for 10 minutes and then lowered. The result was that the copper impregnated only the samples with the tungsten coatings. In the other cases, no composite was formed; a small ball of copper lay on top of the particles bed.

### Example 2

Similar to example 1, but the process was carried out in a vacuum at 10 Pa, in a stainless steel chamber heated inductively, with a temperature of 1130° C. attained for 6 minutes. The result was the same as in example 1: only the diamond particles with the tungsten coating were infiltrated by the copper.

### Example 3

1 g of synthetic diamond SDB 1085 35/45 (De Beers) having a particle size of 350-500 μm and surface roughness Ra=12 nm having a continuous single-layered tungsten (W) coating of mass fraction x=1.2%, weight-average thickness h=110 nm and average surface roughness Ra=40 nm, was poured into a graphite mold measuring 5 mm in diameter to form a dense bed, on top of which was placed 1.50 g (C=1.50) of oxygen-free electronic copper. The mold was placed inside a cylindrical chamber, 36 mm in diameter, made of chromium-nickel steel, encircled within the heating zone by an inductor. By a permanent vacuum pumping to pressure of 10 Pa, the chamber was heated to 1130° C. over a period of 6 minutes, maintained at 1130° C. for 5 minutes, cooled to 100° C., then unsealed. A composite composed of diamond, tungsten carbide and copper was removed from the mold, having the shape of a cylinder measuring Ø5×24 mm. The pycnometric density of the composite was measured as 5.54 g/cm³, the closed porosity as 0.4%, the volume fraction of the diamond as 63%, the thermal conductivity (TC) as 910 W/(m*K), the coefficient of linear thermal expansion (CTE) as 6.9 ppm/K, and the longitudinal ultrasound velocity V_{L} as 9.1 km/s.

### Example 4

Similar to example 3, but the tungsten coating on the diamond had a composition W—W₂C, thickness h 6 nm and roughness Ra 20 nm. As a result, infiltration not occurred (an ingot of copper stayed above a bed of diamond).

### Example 5

Similar to example 3, but a continuous single-layered tungsten coating had a thickness h 20 nm and roughness Ra 25 nm. As a result, 0.02 g of diamond grains with coating were not impregnated by copper (remained in the form of separate particles), and the obtained composite had defects (cavities, particles breakoff from the surface).

### Example 6

Similar to example 3, but a continuous single-layered tungsten carbide WC coating on the diamond had thickness h 50 nm and roughness Ra 32 nm. As a result, the obtained composite had a pycnometric density of 5.28 g/cm³, a closed porosity of 4.8%, a volume fraction of diamond of 60%, a TC of 730 W/(m*K), and a longitudinal sound velocity of 8.5 km/s.

### Example 7

Similar to example 3, but the thickness of the tungsten coating on the diamond was 130 nm and surface roughness Ra=40 nm. The resulting composite had a pycnometric density of 5.46 g/cm³, a closed porosity of 2.0%, a volume fraction of diamond of 62%, a TC of 830 W/(m*K).

### Example 8

Similar to example 3, but the tungsten coating on the diamond had thickness h 320 nm and roughness Ra 80 nm. The resulting composite had a pycnometric density of 5.51 g/cm³, a closed porosity of 2.2%, a percentage by volume of diamond of 62%, a TC of 580 W/(m*K), CTE of 8.3 ppm/K, and a longitudinal sound velocity of 7.7 km/s.

### Example 9

Similar to example 3, but AS-160 200/160 synthetic diamond with a particle size of 160-200 μm and a surface roughness Ra 4 nm was used, covered with a layer of tungsten carbide WC of h=130 nm thickness and Ra=25 nm roughness. The resulting composite had a pycnometric density of 5.50 g/cm³, a closed porosity of 2.3%, a volume fraction of diamond of 62%, a TC of 680 W/(m*K), CTE of 7.6 ppm/K, and a longitudinal sound velocity of 8.4 km/s.

### Example 10

Similar to example 9, but AS-160 200/160 synthetic diamond was coated by a composition WC—W₂C of 150 nm thickness h and 25 nm roughness Ra, and 1.09 g of coated diamond was used (C=1.38). The resulting composite had a pycnometric density of 5.49 g/cm³, a closed porosity of 0.8%, a volume fraction of diamond of 63%, a TC of 740 W/(m*K).

### Example 11

Similar to example 9, but AS-160 200/160 synthetic diamond was coated by a composition W—WC—W₂C of 290 nm thickness h and 32 nm roughness Ra, and 1.12 g of coated diamond was used (C=1.34). The resulting composite had a pycnometric density of 5.59 g/cm³, a closed porosity of 0.3%, a volume fraction of diamond of 63%, and a TC of 660 W/(m*K).

### Example 12

Similar to example 3, but the tungsten coating on the diamond SDB 1085 35/45 had thickness h 230 nm and roughness Ra 63 nm, 1.75 g of silver was used in place of copper and a maximum temperature of 1000° C. was held for 10 minutes. As a result, the composite had a pycnometric density of 5.99 g/cm³, a closed porosity of 3.1%, a volume fraction of diamond of 61%, a TC of 830 W/(m*K), CTE of 8.6 ppm/K, and a longitudinal sound velocity of 7.8 km/s.

### Example 13

Similar to example 3, but the tungsten coating on the diamond had thickness h 230 nm and roughness Ra 63 nm, 1.67 g of silver-copper eutectic alloy (composition 72% wt. Ag-28% wt. Cu) was used in place of copper and a maximum temperature of 980° C. was held for 10 minutes. As a result, the composite had a pycnometric density of 5.85 g/cm³, a closed porosity of 2.5%, a volume fraction of diamond of 62%, a TC of 690 W/(m*K) and CTE of 8.2 ppm/K.

### Example 14

Similar to example 3, but diamond with the coating of mixed tungsten-molybdenum composition having surface roughness of Ra=50 nm was used, atomic ratio Mo/W=1:10 by micro-X-ray spectral analysis, total weight-average thickness was 160 nm. The resulting composite had a pycnometric density of 5.50 g/cm³, a closed porosity of 1.4%, a volume fraction of diamond of 62%, a TC of 540 W/(m*K).

### Example 15

Similar to example 3, but the graphite mold with the channel of the rectangular form with cross section 3×10 mm was used, the weight of diamond filler with tungsten coating was 2,00 g, weight of copper was 3,00 g. As a result, the composite had the shape of a plate of 3×10×31 mm size. The density of a composite calculated from the sample dimensions has made 5.38 g/cm³, porosity—3%.

### Example 16

Similar to example 10 for AS-160 200/160 synthetic diamond, but a graphite mold having a channel of rectangular form with cross section of 2×10 mm was used, the weight of diamond filler with WC—W₂C coating was 0.725 g, and the weight of copper was 1.000 g. As a result, the composite had the shape of a plate of 2×10×16 mm size. The density of a composite calculated from the sample dimensions has made 5.40 g/cm³, porosity—3%.

As seen from results of the experiments presented in examples 3, 6, 8, 9, 12, the composites obtained are characterized by values of longitudinal sound velocity of 7.7-9.1 km/s, that is intermediate between corresponding values for diamond filler (V_{L}=12 km/s) and metal of a matrix (4.8 km/s for copper and 3.6 km/s for silver). It testifies to high adhesion on the matrix/coating and the coating/diamond boundaries, and also about good mechanical properties of the obtained composites. For example, the module of elasticity E is proportional to V_{L}². Accordingly, for the obtained composites elasticity module has high enough value, also intermediate between corresponding values for filler (E≈900 GPa for diamond) and matrixes (E=130 GPa for copper, 71 GPa for silver).

As seen from the results of experiments presented in examples 3, 8, 9, 12, 13, the composites obtained have a coefficient of thermal expansion of 7-9 ppm/K and meet this criterion for compatibility with semiconductor materials (GaN, Si, GaAs, etc. have CTE 3-7 ppm/K); i.e. the composites manufactured by the proposed method provide reliable coupling to semiconductor elements in heat-conducting designs.

Specific electric resistance of a composite r can be estimated by the following additive formula:

$$\frac{1}{r} \approx ( \frac{1}{{r}_{m}} ) {v}_{m} + ( \frac{1}{{r}_{d}} ) {v}_{d} \qquad ( 12 )$$

where 1/r=specific electroconductivity; rₘ=specific electric resistance of a matrix; vₘ≈1−v_{d}=a volume fraction of a matrix. Owing to small thickness of a coating, it makes a minor contribution to the electrical conductivity of the composite. Diamond is a dielectric (r_{d}>10¹⁶ μΩ*cm). For copper rₘ=1.74 μΩ*cm, for silver rₘ=1.47 μΩ*cm. As a result r≈rₘ/vₘ. At diamond volume fraction of 62% a diamond-copper or diamond-silver composite has specific electric resistance about 5 μΩ*cm.

The advantages of the proposed method are the simplicity of the apparatus used, the short time period required for infiltration, and further advantage is that the method of the invention imposes practically no limitations on configuration and size of the products obtained. Obtaining of items of the various forms, including with cavities and holes is possible. The products can be made in final or close to the final shape so additional processing is not required or is insignificant. Other advantages of a method provided according to the present invention include the following:
the number of stages is reduced to a minimum (multilayered coatings are not applied, it is not required pressure compacting before infiltration);
accessible raw material are used (the alloys containing carbide-forming elements are not applied for infiltration);
the heating equipment with precision temperature control is not required;
infiltrating process can be realized without the aid of pressure (mechanical or gas).

The steps of coating diamond particles (to obtain an intermediate filler material) and the step of metal infiltration (to produce a composite) can be separated, i.e. carried out at various times in different places.

The products can be easily fixed to metal constructional elements by means of soldering. The materials produced have an isotropic TC of more than 500 W/(m*K) and a high electrical conductivity. Due to its electroconductivity the composite may be subjected to electrical discharge machining to achieve the final product form.

Those skilled in the art will appreciate that the invention described herein is susceptible to variations and modifications other than those specifically described. It is to be understood that the invention includes all such variations and modifications. The invention also includes all of the steps, features, compositions and compounds referred to or indicated in this specification, individually or collectively, and any and all combinations or any two or more of said steps or features.

The present invention is not to be limited in scope by the specific examples described herein. Functionally equivalent products, compositions and methods are clearly within the scope of the invention, which is defined in the attached claims.

I claim:

1. A diamond-metal composite having a thermal conductivity above 500 W/(m*K), comprising coated diamond particles embedded in a metal matrix having a thermal conductivity of not less than 300 W/(m*K), wherein the particles are coated with a continuous single-layered high surface area coating comprising a metal and/or a carbide of a carbide-forming element selected from IV-VI Groups of the Periodic Table, the coating having an average thickness of 30 to 500 nm and an average surface roughness Ra not less than 20 nm, and wherein the metal of the matrix binds to the said coating by forming interface of high surface area.

2. The composite of claim 1, wherein the carbide-forming element is selected from tungsten (W), molybdenum (Mo), chromium (Cr), titanium (Ti), zirconium (Zr), niobium (Nb), tantalum (Ta).

3. The composite of claim 1, wherein the coating comprises at least one of tungsten (W), tungsten semicarbide (W₂C), tungsten monocarbide (WC), or a combination thereof.

4. A composite of claim 1, wherein the carbide forming material in addition to the said carbide-forming element comprises 0.1-10% (at.) of at least one other element selected from B, Co, Cr, Fe, Hf, La, Mn, Mo, Nb, Ni, Pd, Pt, Re, Si, Ta, Ti, V, W, Y, Zr.

5. A method for manufacturing a composite material having thermal conductivity above 500 W/(m*K), comprising a metal matrix embedded with diamond particles, the method comprising the steps of:
forming on the said diamond particles a continuous single-layered high surface area coating comprising a metal and/or a carbide of a carbide-forming element selected from IV-VI Groups of the Periodic Table, the coating having a thickness of 30 to 500 nm and surface roughness Ra not less than 20 nm,
providing a Group IB of Periodic Table metal or metal alloy having a thermal conductivity of not less than 300 W/(m*K), and
infiltrating the said metal or metal alloy in the molten form into the dense bed of coated diamond particles under conditions providing the metal of the matrix binds to the said coating forming interface of high surface area.

6. A method of claim 5, wherein the carbide-forming element is selected from tungsten (W), molybdenum (Mo), chromium (Cr), titanium (Ti), zirconium (Zr), niobium (Nb), tantalum (Ta).

7. A method of claim 5 wherein the continuous high surface area coating is deposited by a process selected from chemical vapor deposition (CVD), physical vapor deposition (PVD), deposition from salt melt, co-sintering by applying fine particles of reactant substance on the surface of diamond particles with subsequent heat treatment, diffusion coating by reacting diamond particles with a powder of a reactant substance or a mixture of reactant powders.

8. A method of claim 5, wherein the infiltration is carried out in a vacuum or non-oxidizing atmosphere, such as in the hydrogen or inert gas.

9. A method of claim 5, wherein the infiltration is carried out at a temperature 900-1200° C., preferably 980-1130° C.

10. A method of claim 5, wherein the step of infiltration is a pressureless process.

11. A method of claim 5, wherein the step of infiltration is performed with the aid of 0.1-100 MPa pressure.

12. A diamond-metal composite having a thermal conductivity above 500 W/(m*K), comprising coated diamond particles embedded in a metal matrix having a thermal conductivity of not less than 300 W/(m*K), wherein the particles are coated with a single-layered continuous coating of from 5 to 500 nm thickness, the coating comprising a metal and/or a carbide of a carbide-forming element selected from IV-VI Groups of the Periodic Table.

13. The composite of claim 12, wherein the carbide-forming element is selected from tungsten (W), molybdenum (Mo), chromium (Cr), titanium (Ti), zirconium (Zr), niobium (Nb), tantalum (Ta) and/or a combination thereof.

14. A composite of claim 12, wherein the coating additionally comprises 0.1-10% (at.) of at least one other element selected from B, Co, Cr, Fe, Hf, La, Mn, Mo, Nb, Ni, Pd, Pt, Re, Si, Ta, Ti, V, W, Y, Zr.

15. A method for manufacturing a composite material having a thermal conductivity higher than 500 W/(m*K), comprising a metal matrix embedded with coated diamond particles, the method comprising the steps of:
forming on the said diamond particles a single-layered continuous coating comprising a metal and/or carbide of a carbide-forming element selected from IV-VI Groups of the Periodic Table, the coating having a thickness of 5-500 nm,
providing Group IB of the Periodic Table metal or metal alloy having a thermal conductivity of not less than 300 W/(m*K), and
infiltrating the said metal or metal alloy in the molten form into the packed bed of coated diamond particles with the aid of 0.1-100 MPa pressure, providing the metal of the matrix binds to the coating to form the said composite material.

16. A method of claim 15, wherein the coating is formed of at least one of the following: tungsten (W), tungsten semicarbide (W₂C), tungsten monocarbide (WC), molybdenum (Mo), molybdenum semicarbide (Mo₂C), molybdenum monocarbide (MoC), as well as Cr, Ti, Zr, Nb, Ta and/or carbides thereof.

17. A method of claim 15 wherein the coating is deposited by a process selected from chemical vapor deposition (CVD), physical vapor deposition (PVD), deposition from salt melt, co-sintering by applying fine particles of reactant substance on the surface of diamond particles with subsequent heat treatment, diffusion coating by reacting diamond particles with a powder of a reactant substance or a mixture of reactant powders.

18. A method of claim 15, wherein the infiltration is carried out in a vacuum or non-oxidizing atmosphere, such as in the hydrogen or inert gas.

19. A heat sink, for use in a semiconductor or vacuum tube electronic device, comprising a composite material of claim 1.

20. A heat sink, for use in a semiconductor or vacuum tube electronic device, comprising a composite material of claim 12.
